(19) United States
(12) Patent Application Publication
(10) Pub. No.: US 2012/0025390 A1
(43) Pub. Date: Feb. 2, 2012

(54) SEMICONDUCTOR DEVICE AND METHOD FOR FABRICATING THE SAME

(76) Inventor: A-Rum JEONG, Gyeonggi-do (KR)

(21) Appl. No.: 12/948,262

(22) Filed: Nov. 17, 2010

(30) Foreign Application Priority Data
Jul. 28, 2010 (KR) 10-2010-0072765

(51) Int. Cl. H01L 23/48; H01L 21/60

(52) U.S. Cl. 257/773; 438/667; 257/E23.01; 257/E21.506

(57) ABSTRACT

A semiconductor device includes a plurality of storage node contact plugs passing through a first interlayer dielectric layer, a plurality of storage nodes in contact with the storage node contact plugs, each including a first electrode having a pillar shape and a second electrode spaced apart from the first electrode by a certain distance and surrounding the first electrode, and a second interlayer dielectric layer filling a gap between the second electrodes of neighboring storage nodes.

### CROSS-REFERENCE TO RELATED APPLICATION

The present application claims priority of Korean Patent Application No. 10-2010-0072765, filed on Jul. 28, 2010, which is incorporated herein by reference in its entirety.

### BACKGROUND OF THE INVENTION

Exemplary embodiments of the present invention relate to a semiconductor fabrication technology, and more particularly, to a capacitor for use in a semiconductor device and a method for fabricating the same.

As the integration density of semiconductor memory devices, e.g., DRAM, increases, research has been conducted to ensure a necessary capacitance within a limited area. In this regard, a capacitor having a three-dimensional storage node, e.g., a cylindrical structure, has been introduced.

FIGS. 1A to 1C are cross-sectional views illustrating a conventional method for fabricating a capacitor for use in a semiconductor device.

Referring to FIG. 1A, an interlayer dielectric layer 12 is formed on a substrate 11 in which a predetermined structure is formed, and storage node contact plugs 13 passing through the interlayer dielectric layer 12 are formed.

An etch stop layer 14 and an isolation insulation layer 15 are sequentially formed on the interlayer dielectric layer 12 and the storage node contact plugs 13. The isolation insulation layer 15 and the etch stop layer 14 are sequentially etched to form storage node holes 16 exposing the storage node contact plugs 13.

Referring to FIG. 1B, storage nodes 17 are formed inside the storage node holes 16, and the isolation insulation layer 15 is removed by a wet dip-out process.

Referring to FIG. 1C, a dielectric layer 18 is formed along the surface of the structure including the storage nodes 17, and a plate electrode 19 is formed on the dielectric layer 18.

However, as the integration density of the semiconductor device increases, the height of the storage node 17 is to be increased in order to ensure a necessary capacitance within a limited area. Hence, during the wet dip-out process, the storage nodes 17 are likely to lean or be pulled out, resulting in reduction in the yield of the semiconductor device.

To address these concerns, a gap between the storage nodes 17 is filled by a support layer to prevent them from leaning or being pulled out during the wet dip-out process. However, the use of the support layer increases the process steps. Consequently, a manufacturing time and a manufacturing cost may be increased.

### SUMMARY OF THE INVENTION

Exemplary embodiments of the present invention are directed to a semiconductor device, which is capable of ensuring a necessary capacitance within a limited area, and a method for fabricating the same.

Exemplary embodiments of the present invention are directed to a semiconductor device, which is capable of preventing failures, such as leaning or pulled-out storage nodes, and a method for fabricating the same.

In accordance with an exemplary embodiment of the present invention, a semiconductor device includes a plurality of storage node contact plugs passing through a first interlayer dielectric layer, a plurality of storage nodes in contact with the storage node contact plugs, each including a first electrode having a pillar shape and a second electrode spaced apart from the first electrode by a certain distance and surrounding the first electrode, and a second interlayer dielectric layer filling a gap between the second electrodes of neighboring storage nodes.

In accordance with another exemplary embodiment of the present invention, a method for fabricating a semiconductor device includes forming a plurality of storage node contact plugs passing through a first interlayer dielectric layer and forming a first electrode having a pillar shape, forming a first spacer surrounding the sidewall of each of the first electrodes, forming a second electrode and a second spacer over each of the first spacers to surround the first electrodes, forming a second interlayer dielectric layer filling a gap between neighboring second electrodes, and performing a planarization process to separate the first electrodes and the second electrodes and expose the top surfaces of the first and second spacers.

### BRIEF DESCRIPTION OF THE DRAWINGS

FIGS. 1A to 1C are cross-sectional views illustrating a conventional method for fabricating a capacitor for use in a semiconductor device.

FIG. 2A is a cross-sectional view of a semiconductor device in accordance with an exemplary embodiment of the present invention.

FIG. 2B is a plan view taken along line A-A′ of FIG. 2A.

FIGS. 3A to 3H are cross-sectional views illustrating a method is for fabricating a semiconductor device in accordance with an exemplary embodiment of the present invention.

FIG. 4A is a plan view taken along line A-A′ of FIG. 3A.

FIG. 4B is a plan view taken along line A-A′ of FIG. 3C.

FIG. 4C is a plan view taken along line A-A′ of FIG. 3F.

FIG. 4D is a plan view taken along line A-A′ of FIG. 3H.

FIG. 5A is a cross-sectional view of a semiconductor device in accordance with another exemplary embodiment of the present invention.

FIG. 5B is a plan view taken along line A-A′ of FIG. 5A.

FIGS. 6A to 6D are cross-sectional views illustrating a method for fabricating a semiconductor device in accordance with another exemplary embodiment of the present invention.

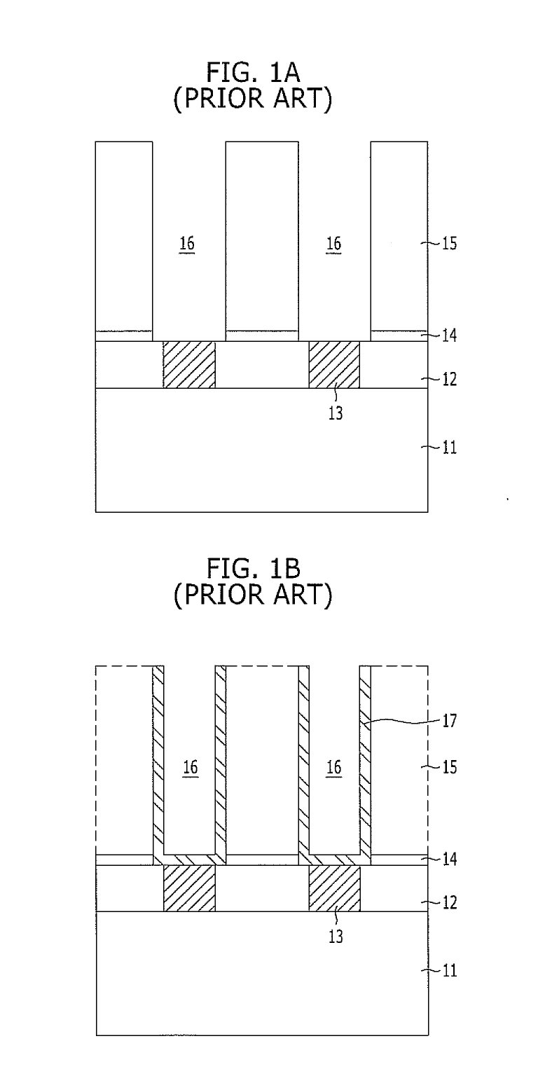

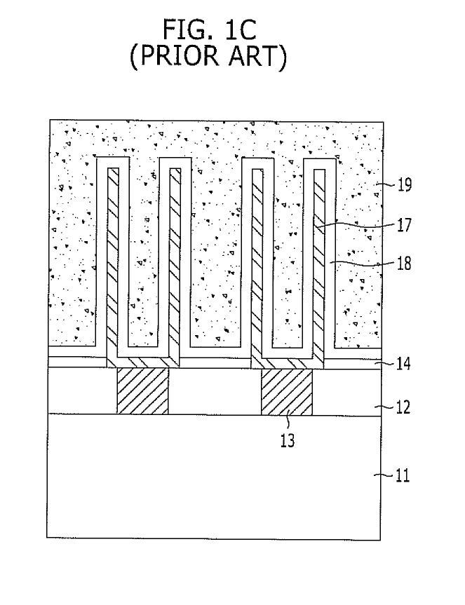

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate, but also a case where a third layer exists between the first layer and the second layer or the substrate.

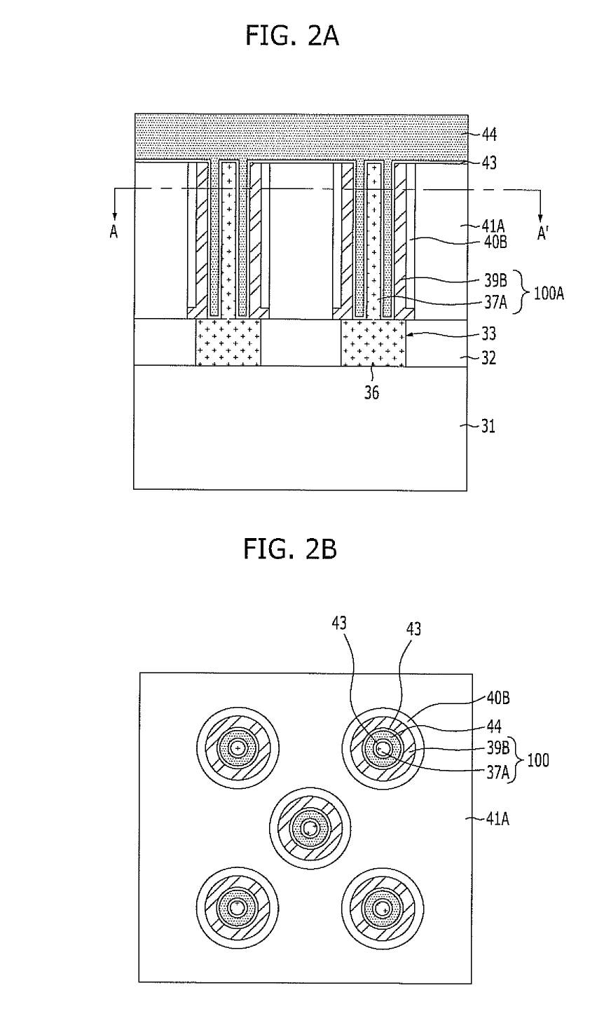

FIGS. 2A and 2B illustrate a semiconductor device in accordance with an exemplary embodiment of the present invention. Specifically, FIG. 2A is a cross-sectional view of the semiconductor device in accordance with the exemplary embodiment of the present invention, and FIG. 2B is a plan view taken along line A-A′ of FIG. 2A.

Referring to FIGS. 2A and 2B, the semiconductor device in accordance with the exemplary embodiment of the present invention includes a substrate 31, a first interlayer dielectric layer 32, a plurality of storage node contact plugs 36, a plurality of storage nodes 100A, a second interlayer dielectric layer 41A, a dielectric layer 43, and a plate electrode 44. A certain structure is formed in the substrate 31. The first interlayer dielectric layer 32 is formed on the substrate 31. The storage node contact plugs 36 are formed to pass through the first interlayer dielectric layer 32. The storage nodes 100A are formed to be in contact with the storage node contact plugs 36. Each of the storage nodes 100A includes a first electrode 37A, having a pillar shape, and a second electrode 39B, which is spaced apart from the first electrode 37A by a certain distance and surrounds the first electrode 37A. The second interlayer dielectric layer 41A fills a gap between neighboring second electrodes 39B. The dielectric layer 43 is formed on the exposed storage node 100A. The plate electrode 44 is formed on the dielectric layer 43 to fill a gap between the first electrode 37A and the second electrode 39B of each of the storage nodes 100A.

The storage node contact plugs 36 are arranged along a zigzag line in order to maximally ensure a space where the storage nodes 100A are to be formed. Therefore, the storage nodes 100A in contact with the storage node contact plugs 36 are also arranged along a zigzag line.

The first electrode 37A having a pillar shape is coupled to the center of the storage node contact plug 36. At this time, the first electrode 37A and the storage node contact plug 36 may be formed of the same material at the same time. Therefore, the storage node contact plug 36 protrudes vertically in a direction perpendicular to the top surface of the substrate 31 to form the first electrode 37A, and the first electrode 37A may be integrally formed with the storage node contact plug 36.

The second electrode 39B surrounding the first electrode 37A has a donut-shaped cylindrical structure and is coupled to the edge of the storage node contact plug 36. While having a donut-shaped cylindrical structure, the second electrode 39B may have an L-shaped structure in which its lower portion extends in a direction away from the center of the cylinder, in order to increase the contact area with the storage node contact plug 36 and improve its support strength. The structure in which the second electrode 39B is spaced apart from the first electrode 37A by a certain distance provides a space where the dielectric layer 43 and the plate electrode 44 are to be formed. The second electrode 39B and the first electrode 37A may be formed of the same material or different materials.

The storage node 100A, including the first electrode 37A and the second electrode 39B, may have a greater contact area with the dielectric layer 43 than the conventional cylindrical storage node. Therefore, a greater capacitance for the semiconductor device may be provided within the limited area.

The storage node contact plug 36, the first electrode 37A, and the second electrode 39B may include a silicon layer or a metallic layer. The silicon layer may include a polysilicon layer, and the metallic layer may include a metal layer, a metal oxide layer, a metal nitride layer, or a metal silicide layer.

The first interlayer dielectric layer 32 isolates the substrate 31 from the capacitor including the storage node 100A, the dielectric layer 43, and the plate electrode 44. The second interlayer dielectric layer 41A prevents the leaning or pulling-out of the storage node 100A during subsequent processes by filling a gap between the neighboring second electrodes 39B.

The first interlayer dielectric layer 32 and the second interlayer dielectric layer 41A may include any one selected from the group consisting of an oxide layer, a nitride layer, and an oxynitride layer. The first interlayer dielectric layer 32 and the second interlayer dielectric layer 41A may be formed of the same material or different materials.

The dielectric layer 43 is formed to cover the exposed top surface and sidewall of the first electrode 37A, the exposed top surface and inner wall of the second electrode 39B, and the top surface of the second interlayer dielectric layer 41A. The plate electrode 44 is formed on the dielectric layer 43 and fills a gap between the first electrode 37A and the second electrode 39B.

Since the semiconductor device having the above-described structure in accordance with this exemplary embodiment of the present invention includes the storage node 100A provided with the first electrode 37A, having a pillar shape, and the second electrode 39B, surrounding the first electrode 37A, the capacitance for the semiconductor device may be stably provided within the limited/minimized area.

Also, since the second interlayer dielectric layer 41A filling the gap between the second electrodes 39B is provided, the leaning or pulling-out of the storage node 100A may be prevented during subsequent processes.

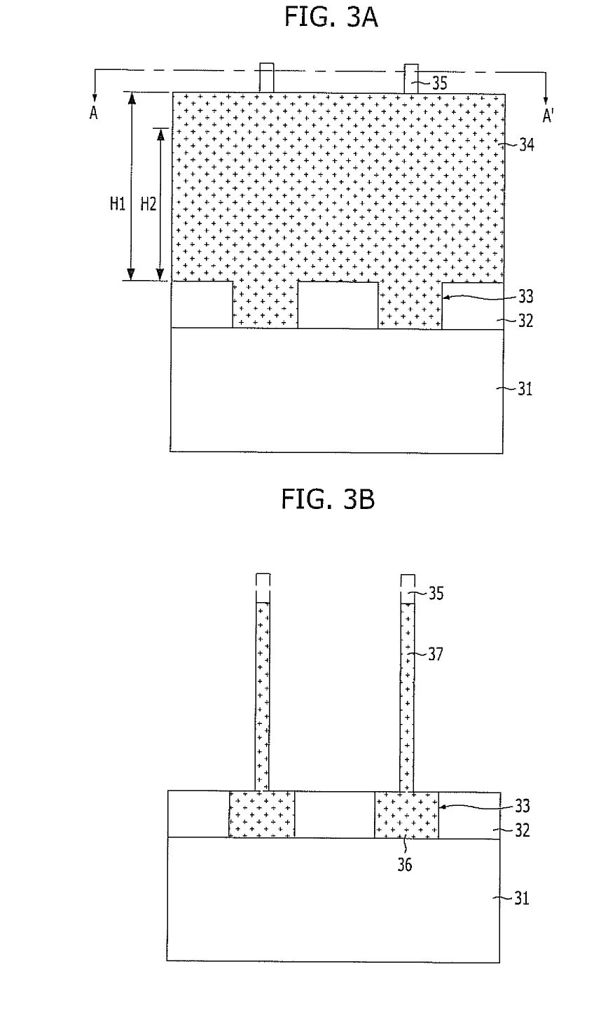

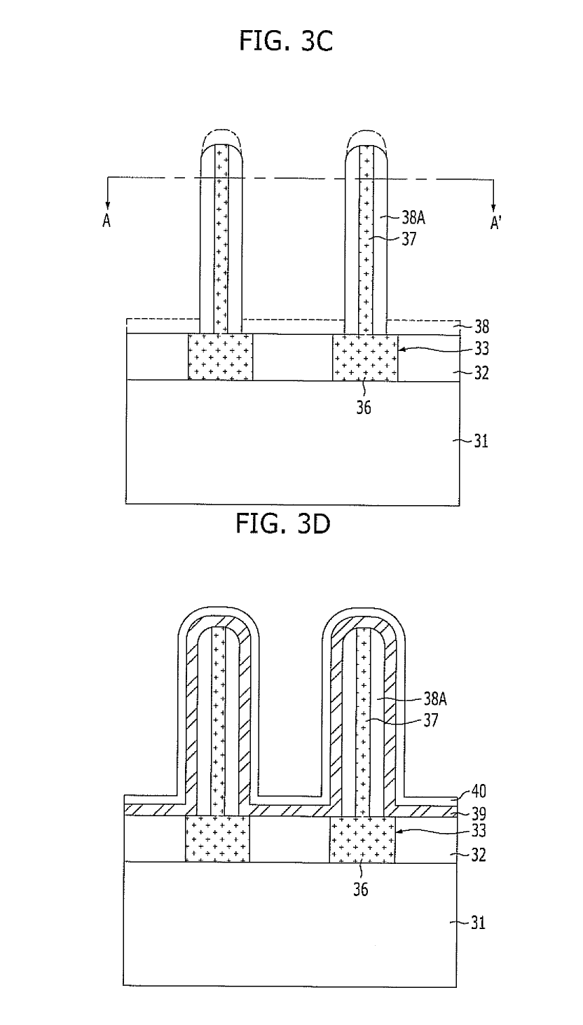

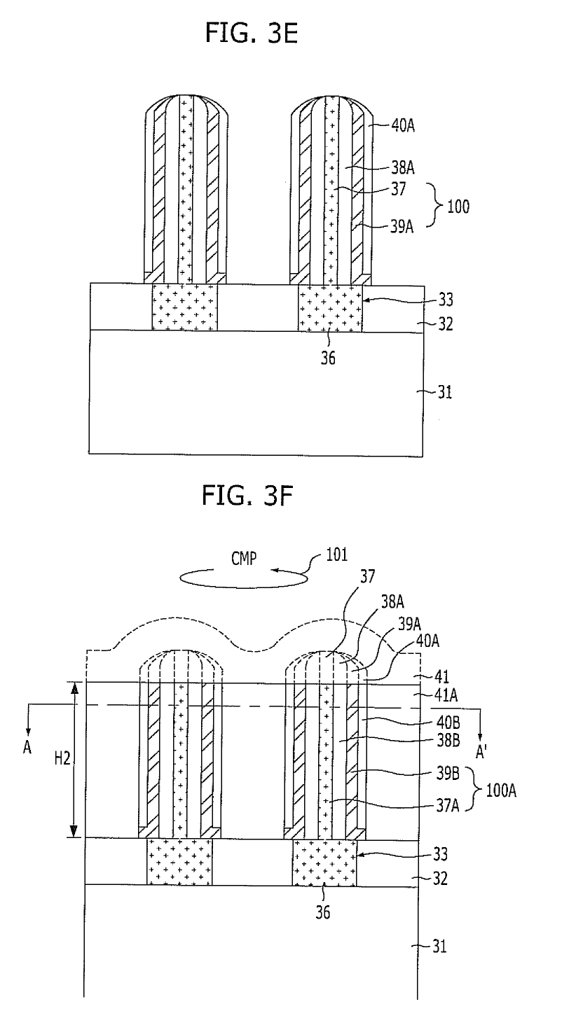

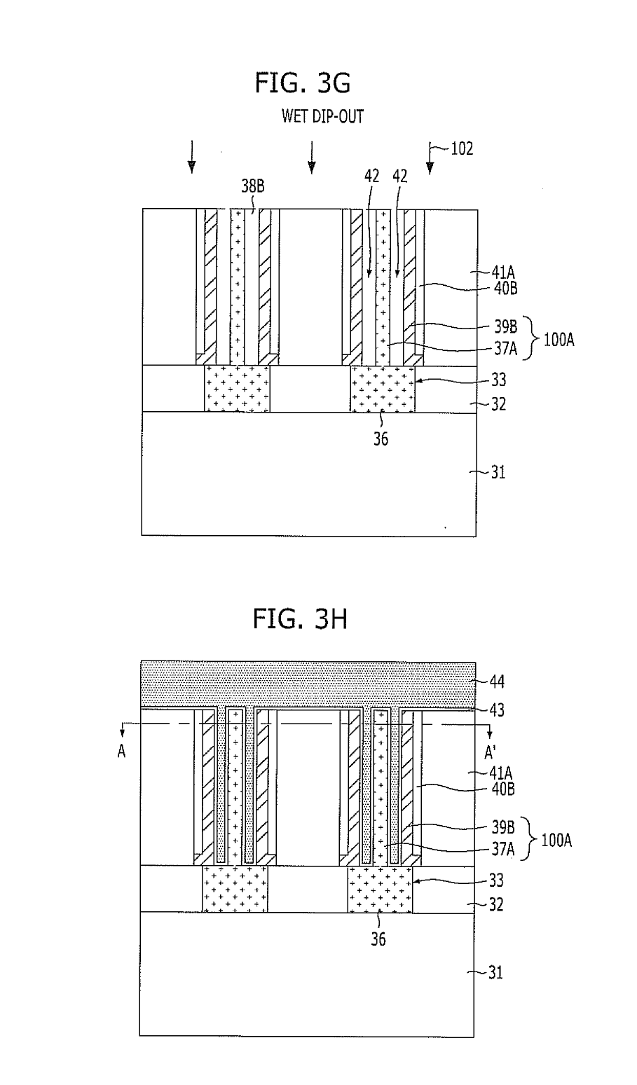

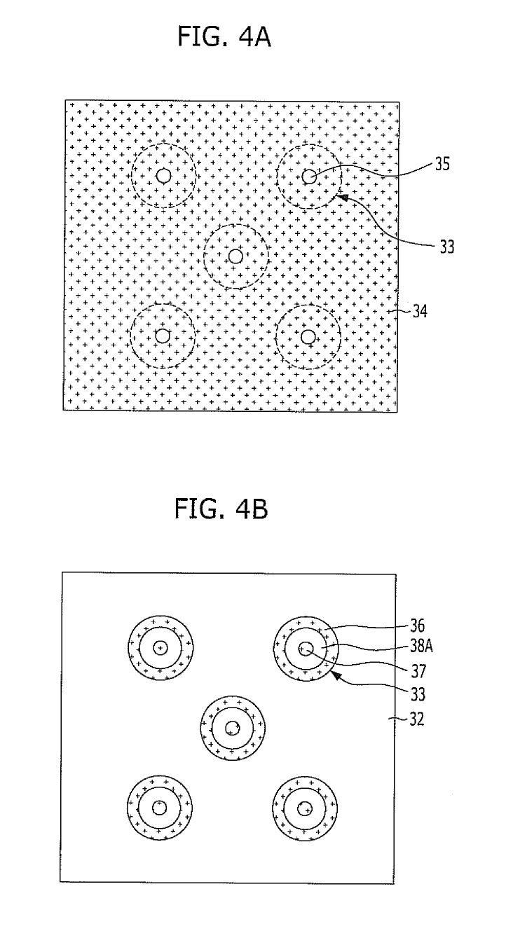

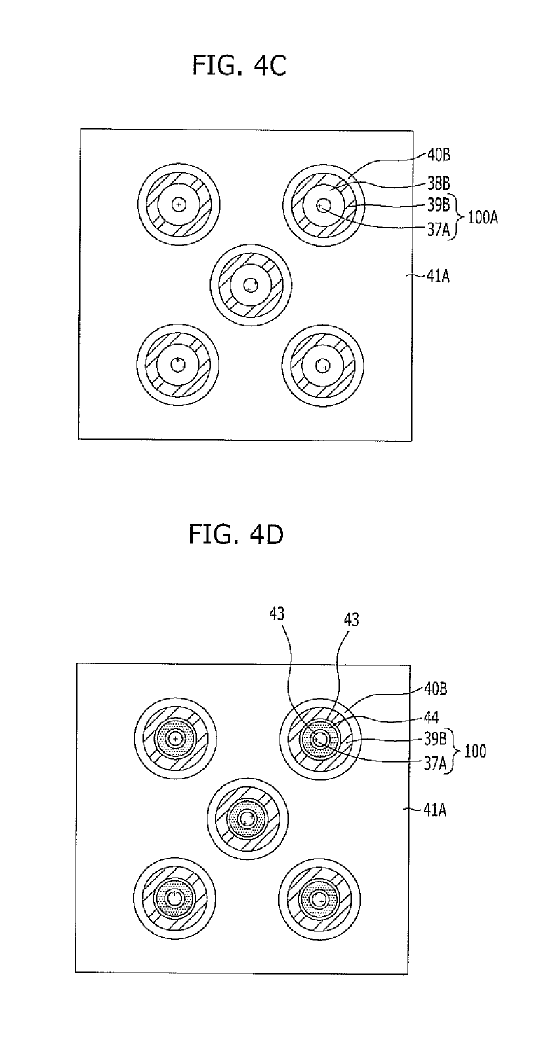

FIGS. 3A to 3H are cross-sectional views illustrating a method for fabricating a semiconductor device in accordance with an exemplary embodiment of the present invention. FIG. 4A is a plan view taken along line A-A′ of FIG. 3A.

Referring to FIGS. 3A and 4A, a first interlayer dielectric layer 32 is formed on a substrate 31 in which a certain structure is formed. At this time, the first interlayer dielectric layer 32 may include any one selected from the group consisting of an oxide layer, a nitride layer, and oxynitride layer.

The first interlayer dielectric layer 32 is selectively etched to form storage node contact holes 33. The storage node contact holes 33 may be formed along a zigzag line in order to more effectively utilize a space where storage nodes are to be formed.

A first conductive layer 34 is formed to completely fill the storage node contact holes 33 and also cover the interlayer dielectric layer 34. The first conductive layer 34 may include a silicon layer or a metallic layer. The silicon layer includes a polysilicon layer, and the metallic layer includes a metal layer such as a tungsten (W) layer, a metal oxide layer such as an iridium oxide (IrO₂) layer, a metal nitride layer such as a titanium nitride (TiN) layer, or a metal silicide layer such as a titanium silicide (TiSi) layer.

The height H1 of the first conductive layer 34 is higher than the height H2 of a subsequent storage node with respect to the top surface of the first interlayer dielectric layer 32.

A mask pattern 35 is formed on the first conductive layer 34. The mask pattern 35 may partially cover the top surface of the first conductive layer 34 directly above the storage node contact holes 33, and therefore, may be arranged along a zigzag line. The mask pattern 35 may include a stacked layer in which an amorphous carbon layer and a silicon oxynitride layer are stacked.

Referring to FIG. 3B, the first conductive layer 34 is etched using the mask pattern 35 as an etch barrier until the first interlayer dielectric layer 32 is exposed. As a result, a storage node contact plug 36 filling the storage node contact hole 33 and a first electrode 37 having a pillar shape are formed. At this time, the first electrode 37 has a structure that protrudes vertically from a contact hole 33 in a direction perpendicular to the top surface of the substrate 31.

After forming the first electrode 37, the mask pattern 35 is removed.

More specifically, the mask pattern 35 may be removed through a cleaning process. During the cleaning process, a portion of the first electrode 37 may be etched to reduce the diameter of the first electrode 37.

FIG. 4B is a plan view taken along line A-A′ of FIG. 3C. Referring to FIGS. 3C and 4B, an insulation layer 38 for a first spacer is formed along the surface of the structure including the first electrode 37. The insulation layer 38 for a first spacer may include any one selected from the group consisting of an oxide layer, a nitride layer, an oxynitride layer, or a carbon-containing layer. The carbon-containing layer may include an amorphous carbon layer. In the exemplary embodiment shown in FIG. 3C, the insulation layer 38 for a first spacer is formed of nitride, e.g., silicon nitride (Si₃N₄).

An etchback process or a blanket etch process is performed onto the insulation layer 38 to form a first spacer 38A surrounding the first electrode 37. At this time, the first spacer 38A is formed to surround the sidewall of the first electrode 37.

The first spacer 38A is formed to expose the edge of the storage node contact plug 36. This may be achieved by adjusting the deposition thickness during the process of forming the insulation layer 38 for a first spacer. As such, the edge of the storage node contact plug 36 is exposed in order for the storage node contact plug 36 to contact a second electrode, which is to be formed in a subsequent process.

Referring to FIG. 3D, a second conductive layer 39 is formed along the surface of the structure in which the first spacer 38A is formed. At this time, the second conductive layer 39 may include a silicon layer or a metallic layer, and may be formed of the same material as the first conductive layer 34. When the second conductive layer 39 is formed of the same material as the first conductive layer 34, the contact characteristic between the storage node contact plug 36 and the second conductive layer 39 may be improved.

An insulation layer 40 for a second spacer is formed on the second conductive layer 39. At this time, the insulation layer 40 for a second spacer is formed along the surface of the structure including the second conductive layer 39.

The insulation layer 40 for a second spacer may include any one selected from the group consisting of an oxide layer, a nitride layer, an oxynitride layer, and a carbon-containing layer. At this time, the insulation layer 40 for a second spacer is formed of a material having a different etch selectivity from the insulation layer 38 for a first spacer. Therefore, in the exemplary embodiment of FIG. 3D, the insulation layer 40 for a second spacer may be formed of oxide, e.g., silicon oxide (SiO₂).

Referring to FIG. 3E, a second spacer 40A and a second electrode 39A are formed by performing an etchback etch process or a blanket etch process until the first interlayer dielectric layer 32 is exposed. At this time, the second electrode 39A is formed using the second spacer 40A as an etch barrier and has a donut-shaped cylindrical structure which surrounds the first electrode 37. Since the second electrode 39A is formed using the second spacer 40A as an etch barrier, it has an L-shaped structure in which its lower portion extends in a direction of away from the center of the cylindrical structure. The L-shaped structure of the second electrode 39A may ensure a sufficient contact area between the second electrode 39A and the storage node contact plug 36, and also improve the support strength of the second electrode 39A.

Through the above-described processes, a storage node 100 including the first electrode 37 having a pillar shape and the second electrode 39A surrounding the first electrode 37 is formed.

FIG. 4C is a plan view taken along line A-A′ of FIG. 3F. Referring to FIGS. 3F and 4C, a second interlayer dielectric layer 41 filling the gap between the storage nodes 100 is formed. Specifically, the second interlayer dielectric layer 41 is formed over the substrate 31 to fill the gap between the storage nodes 100 and also cover the top surfaces thereof.

The second interlayer dielectric layer 41 may include any one selected from the group consisting of an oxide layer, a nitride layer, and oxynitride layer. At this time, the second interlayer dielectric layer 41 may be formed of the same material as the second spacer 40A. The second interlayer dielectric layer 41 may be formed of the same material as the first interlayer dielectric layer 32.

A planarization process 101 is performed so that the storage node 100 has a predefined height H2 from the top surface of the first interlayer dielectric layer 32. At this time, the planarization process 101 may be performed using chemical mechanical polishing (CMP). The storage node 100, the second interlayer dielectric layer 41, the second spacer 40A, the second electrode 39A, the first spacer 38A, and the first electrode 37 resulting after the planarization process may have a different shape, and therefore, are labeled with reference numerals “100A”, “41”, “40B”, “39B”, “38B”, and “37A”, respectively.

Through the planarization process 101, the first electrode 37A and the second electrode 39B are separated from each other. Also, the first spacer 38B to be removed in a subsequent process is exposed. The upper portions of the first electrode 37A and the second electrode 39B damaged during the processes are removed.

Referring to FIG. 3G, a wet dip-out process 102 is performed to remove the first spacer 38B between the first electrode 37A and the second electrode 39B, thereby forming a storage node hole 42. In the exemplary embodiment shown in FIG. 3G, since the first spacer 38B is formed of nitride, the wet dip-out process 102 may be performed using a phosphoric acid solution. For reference, when the first spacer 38B is formed of oxide, the wet dip-out process 102 may be performed using a buffered oxide etchant (BOE).

According to the prior art, forming a storage node hole results in the removal of a layer between neighboring storage nodes, and thus, the storage nodes may lean or be pulled-out. However, in an exemplary embodiment of the present invention, during the wet dip-out process 102, the first spacer 38B between the first electrode 27A and the second electrode 39B is removed and the second interlayer dielectric layer 41A remains, thereby preventing the leaning or pulling-out of the storage node 100A.

Also, during the wet dip-out process 102, the leaning or pulling-out of the second electrode 39B having a donut-shaped cylindrical structure may be further prevented by the first electrode 37A having a pillar shape. Furthermore, since the second electrode 39B has an L-shaped structure, the leaning or pulling-out of the second electrode 39B during the wet dip-out process 102 may be further effectively prevented.

Meanwhile, the first electrode 37A has a structure which is formed by the protrusion of the storage node contact plug 36 over the substrate 31. That is, since the storage node contact plug 36 and the first electrode 37A are integrally formed, the leaning or pulling-out of the first electrode 37A is prevented.

FIG. 4D is a plan view taken along line A-A′ of FIG. 3H. Referring to FIGS. 3H and 4D, a dielectric layer 43 is formed along the surface of the structure in which the storage node hole 42 is formed. Therefore, the dielectric layer 43 is formed to cover the exposed top surface and sidewall of the first electrode 37A, the exposed top surface and inner wall of the second electrode 39B, and the top surface of the second interlayer dielectric layer 41A.

A plate electrode 44 filling the remaining storage node hole 42 is formed on the dielectric layer 43. The plate electrode 44 has a structure which fills the storage node hole 42 and covers the second interlayer dielectric layer 41A.

In accordance with an exemplary embodiment of the present invention, since the storage node 100A is formed with the first electrode 37A having a pillar shape and the second electrode 39B surrounding the first electrode 37A, the capacitance for the semiconductor device may be stably provided within the limited/minimized area.

Also, the storage node hole 42 is formed by removing the first spacer 38B during the wet dip-out process 102, and the second interlayer dielectric layer 41A filling the gap between the second electrodes 39B is maintained, thereby preventing the leaning or pulling-out of the storage node 100A.

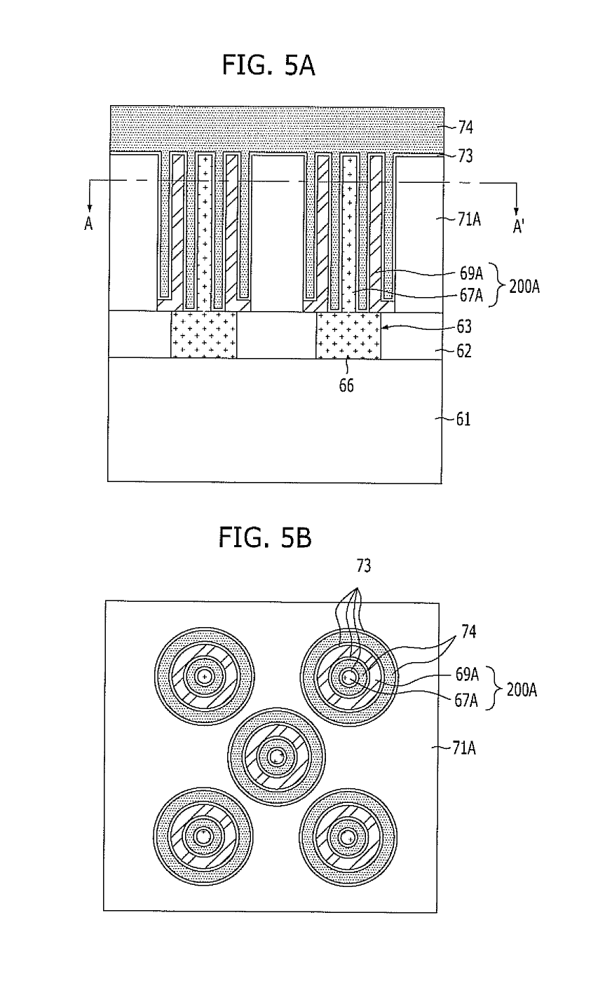

FIGS. 5A and 5B illustrate a semiconductor device in accordance with another exemplary embodiment of the present invention. Specifically, FIG. 5A is a cross-sectional view of the semiconductor device in accordance with another exemplary embodiment of the present invention, and FIG. 5B is a plan view taken along line A-A′ of FIG. 5A.

Referring to FIGS. 5A and 5B, the semiconductor device in accordance with this exemplary embodiment of the present invention includes a substrate 61, a first interlayer dielectric layer 62, a plurality of storage node contact plugs 66, a plurality of storage nodes 200A, a second interlayer dielectric layer 71A, a dielectric layer 73, and a plate electrode 74. A certain structure is formed in the substrate 61. The first interlayer dielectric layer 62 is formed on the substrate 61. The storage node contact plugs 66 are formed to pass through the first interlayer dielectric layer 62. The storage nodes 200A are formed to be in contact with the storage node contact plugs 66. Each of the storage nodes 200A includes a first electrode 67A, having a pillar shape, and a second electrode 69A, which is spaced apart from the first electrode 67A by a certain distance and surrounds the first electrode 67A. The second interlayer dielectric layer 71A is formed to be spaced apart from the second electrode 69A by a certain distance and fills a gap therebetween neighboring storage nodes 200A. The dielectric layer 73 is formed on the exposed storage node 200A. The plate electrode 74 is formed on the dielectric layer 73 to fill a gap between the first electrode 67A and the second electrode 69A.

The storage node contact plugs 66 may be arranged along a zigzag line in order to maximally ensure a space where the storage nodes 200A are to be formed. Therefore, the storage nodes 200A in contact with the storage node contact plugs 66 are also arranged along a zigzag line.

The first electrode 67A having a pillar shape is coupled to the center of the storage node contact plug 66. At this time, the first electrode 67A and the storage node contact plug 66 may be formed of the same material at the same time. Therefore, the storage node contact plug 66 protrudes vertically in a direction perpendicular to the top surface of the substrate 61 to form the first electrode 67A, and the first electrode 67A may be integrally formed with the storage node contact plug 66.

The second electrode 69A surrounding the first electrode 67A has a donut-shaped cylindrical structure and is coupled to the edge of the storage node contact plug 66. While having a donut-shaped cylindrical structure, the second electrode 69A may have an L-shaped structure in which its lower portion extends in a direction away from the center of the cylinder, in order to increase the contact area with the storage node contact plug 66 and improve its support strength. The structure in which the second electrode 69A is spaced apart from the first electrode 67A and the second interlayer dielectric layer 71A by a certain distance provides a space where the dielectric layer 73 and the plate electrode 74 are to be formed. The second electrode 69A and the first electrode 67A may be formed of the same material or different materials.

The storage node 200A, including the first electrode 67A and the second electrode 69A, may have a greater contact area with the dielectric layer 73 than the conventional cylindrical storage node. At this time, since the storage node 200A of this exemplary embodiment of the present invention is spaced apart from the second interlayer dielectric layer 71A, the outer wall of the second electrode 69A is exposed. Hence, the capacitance of the storage node 200A may be greater than that of the storage node 100A shown in FIG. 2A.

The storage node contact plug 66, the first electrode 67A, and the second electrode 69A may include a silicon layer or a metallic layer. The silicon layer may include a polysilicon layer, and the metallic layer may include a metal layer, a metal oxide layer, a metal nitride layer, or a metal silicide layer.

The first interlayer dielectric layer 62 isolates the substrate 61 from the capacitor including the storage node 200A, the dielectric layer 73, and the plate electrode 74. The second interlayer dielectric layer 71A prevents the leaning or pulling-out of the storage node 200A during subsequent processes by filling a gap between the neighboring second electrodes 69A.

The first interlayer dielectric layer 62 and the second interlayer dielectric layer 71A may include any one selected from the group consisting of an oxide layer, a nitride layer, and an oxynitride layer. The first interlayer dielectric layer 62 and the second interlayer dielectric layer 71A may be formed of the same material or different materials.

The dielectric layer 73 is formed to cover the top surface and sidewall of the first electrode 67A, the top surface, inner wall and outer wall of the second electrode 69A, and the top surface of the second interlayer dielectric layer 71A. The plate electrode 74 is formed on the dielectric layer 73 and fills a gap between the first electrode 67A and the second electrode 69A and between the second electrode 69A and the second interlayer dielectric layer 71A.

Since the semiconductor device having the above-described structure in accordance with this exemplary embodiment of the present invention includes the storage node 200A provided with the first electrode 67A, having a pillar shape, and the second electrode 69A, surrounding the first electrode 67A, the capacitance for the semiconductor device may be stably provided within the limited/minimized area. In addition, since the second electrode 69A and the second interlayer dielectric layer 71A are spaced apart from each other by a certain distance to expose the outer wall of the second electrode 69A, the capacitance for the semiconductor device may be more sufficiently provided.

Also, since the second interlayer dielectric layer 71A filling the gap between the second electrodes 69A is provided, the leaning or pulling-out of the storage node 200A may be prevented during subsequent processes.

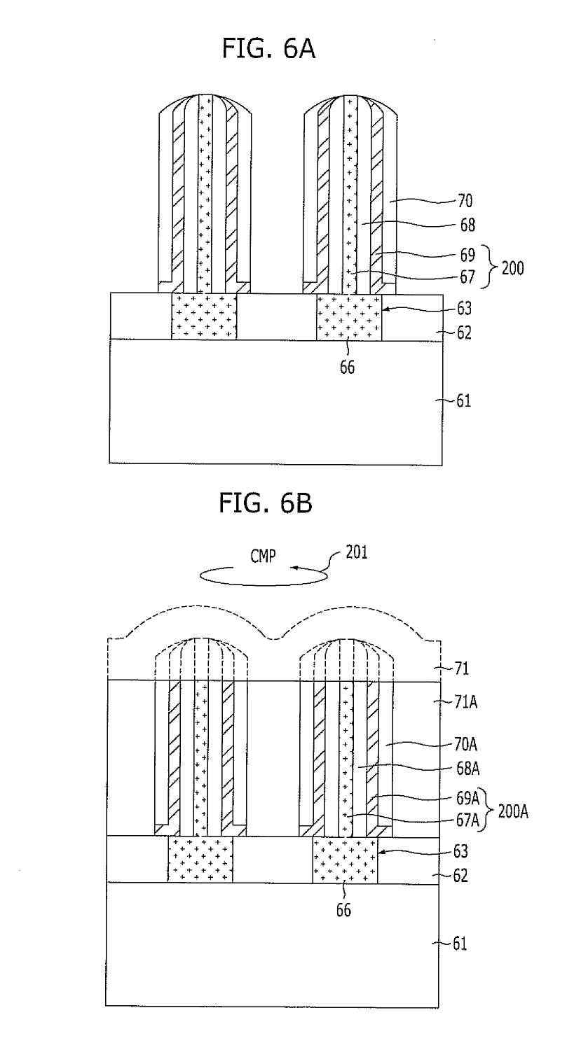

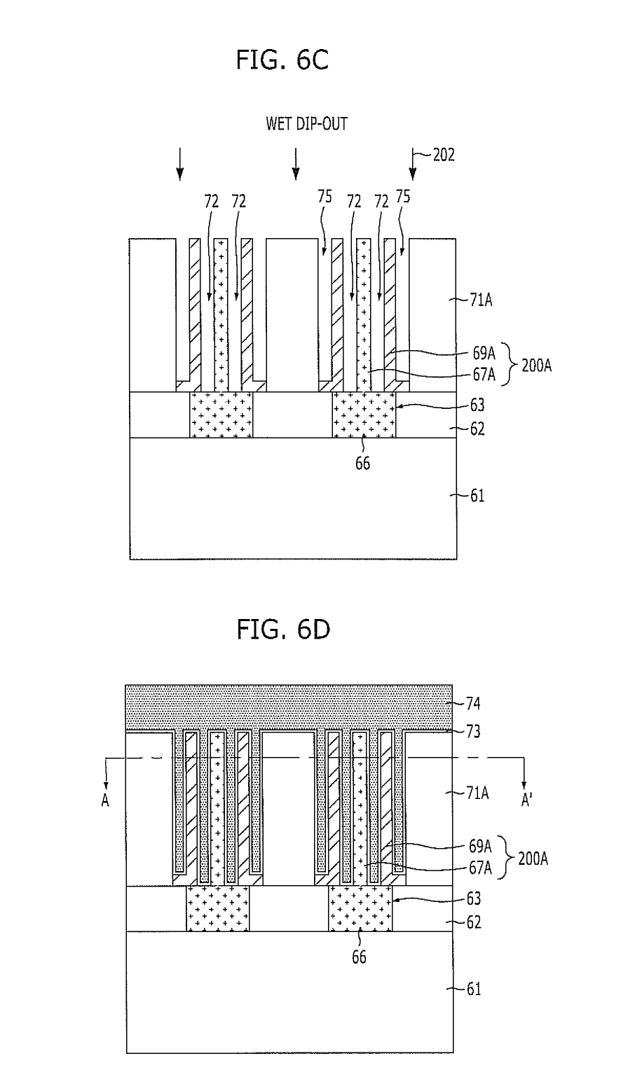

FIGS. 6A to 6D are cross-sectional views illustrating a method for fabricating a semiconductor device in accordance with another exemplary embodiment of the present invention.

Referring to FIG. 6A, a storage node contact plug 66 passing through a first interlayer dielectric layer 62 formed on a substrate 61 in which a certain structure is formed, a storage node 200 including a first electrode 67 having a pillar shape and a second electrode 69 surrounding the first electrode 67, a first spacer 68 surrounding the first electrode 67 and disposed between the first electrode 67 and the second electrode 69, and a second spacer 70 are formed. This structure may be formed in the same manner as illustrated in FIGS. 3A to 3E.

In this exemplary embodiment of the present invention, the first spacer 68 and the second spacer 70 are formed of the same material. It is assumed that the first spacer 68 and the second spacer 70 are formed of nitride, e.g., silicon nitride.

Referring to FIG. 6B, a second interlayer dielectric layer 71 filling the gap between the storage nodes 200 is formed. Specifically, the second interlayer dielectric layer 71 is formed over the substrate 61 to fill the gap between the storage nodes 200 and also cover the top surfaces thereof.

The second interlayer dielectric layer 71 may include any one selected from the group consisting of an oxide layer, a nitride layer, and oxynitride layer. At this time, the second interlayer dielectric layer 71 is formed of a material having an etch selectivity with respect to the first spacer 68 and the second spacer 70. Therefore, in this exemplary embodiment of the present invention, the second interlayer dielectric layer 71 is formed of oxide. The second interlayer dielectric layer 71 may be formed of the same material as the first interlayer dielectric layer 71.

A planarization process 201 is performed so that the storage node 200 has a predefined height from the top surface of the first interlayer dielectric layer 62. At this time, the planarization process 201 may be performed using chemical mechanical polishing (CMP). The storage node 200, the second interlayer dielectric layer 71, the second spacer 70, the second electrode 69, the first spacer 68, and the first electrode 67 resulting after the planarization process may have a different shape, and therefore, are labeled with reference numerals “200A”, “71A”, “70A”, “69A”, “68A”, and “67A”, respectively.

Through the planarization process 201, the first electrode 67A and the second electrode 69A are separated from each other. Also, the first spacer 68A and the second spacer 70A to be removed in a subsequent process are exposed. The upper portions of the first electrode 67A and the second electrode 69A damaged during the processes are removed.

Referring to FIG. 6C, a wet dip-out process 202 is performed to remove the first spacer 68A between the first electrode 67A and the second electrode 69A, thereby forming a first storage node hole 72. At the same time, the second spacer 70A between the second electrode 69A and the second interlayer dielectric layer 71A is removed to form a second storage node hole 75. Due to the first storage node hole 72, the sidewall of the first electrode 67A and the inner wall of the second electrode 69A are exposed. Due to the second storage node hole 75, the outer wall of the second electrode 69A is exposed. In this exemplary embodiment of the present invention, since the first spacer 68A and the second spacer 70A are formed of nitride, the wet dip-out process 202 may be performed using a phosphoric acid solution.

According to the prior art, forming a storage node hole results in the removal of a layer between neighboring storage nodes, and thus, the storage nodes may lean or be pulled-out. However, in this exemplary embodiment of the present invention, during the wet dip-out process 202, the first spacer 68A and the second spacer 70A are selectively removed and the second interlayer dielectric layer 71A remains, thereby preventing the leaning or pulling-out of the storage node 200A.

Also, during the wet dip-out process 202, the leaning or puffing-out of the second electrode 69A having a donut-shaped cylindrical structure may be further prevented by the first electrode 67A having a pillar shape. Furthermore, since the second electrode 69A has an L-shaped structure, the leaning or pulling-out of the second electrode 69A during the wet dip-out process 202 may be further effectively prevented.

Meanwhile, the first electrode 67A has a structure which is formed by the protrusion of the storage node contact plug 66 over the substrate 61. That is, since the storage node contact plug 66 and the first electrode 67A are integrally formed, the leaning or pulling-out of the first electrode 67A is prevented.

Referring to FIG. 6D, a dielectric layer 73 is formed along the surface of the structure in which the first storage node hole 72 and the second storage node hole 75 are formed. Therefore, the dielectric layer 73 is formed to cover the top surface and sidewall of the first electrode 67A, the top surface, inner wall and outer wall of the second electrode 69A, and the top surface of the second interlayer dielectric layer 71A.

A plate electrode 74 filling the remaining first and second storage node holes 72 and 75 is formed on the dielectric layer 73. The plate electrode 74 has a structure which fills the first and second storage node holes 72 and 75 and covers the second interlayer dielectric layer 71A.

According to the method for fabricating the semiconductor device in accordance with this exemplary embodiment of the present invention, since the storage node 200A is formed with the first electrode 67A having a pillar shape and the second electrode 69A surrounding the first electrode 67A, the capacitance for the semiconductor device may be stably provided within the limited/minimized area. In addition, since the second electrode 69A is spaced apart from the second interlayer dielectric layer 71A by a certain distance, the outer wall of the second electrode 69A is exposed. Hence, the capacitance for the semiconductor device may be increased.

Furthermore, during the wet dip-out process 202, the first spacer 68A and the second spacer 70A are selectively removed and the second interlayer dielectric layer 71A remains, thereby preventing the leaning or pulling-out of the storage node 200A. That is, the second interlayer dielectric layer 71A filling the gap between the second electrodes 69A is provided, thereby preventing the leaning or pulling-out of the storage nodes 200A during subsequent processes.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a plurality of storage node contact plugs passing through a first interlayer dielectric layer;
a plurality of storage nodes in contact with the storage node contact plugs, each comprising a first electrode having a pillar shape and a second electrode spaced apart from the first electrode by a certain distance and surrounding the first electrode; and
a second interlayer dielectric layer filling a gap between the second electrodes of neighboring storage nodes.

2. The semiconductor device of claim 1, further comprising:
a dielectric layer disposed over an exposed surface of the storage nodes; and
a plate electrode disposed over the dielectric layer to fill a gap between each of the first electrodes and the second electrodes.

3. The semiconductor device of claim 1, wherein each of the first electrodes is in contact with the center of a corresponding one of the storage node contact plugs, and each of the second electrodes is in contact with the edge of the corresponding one of the storage node contact plugs.

4. The semiconductor device of claim 1, wherein the first electrodes and the storage node contact plugs are formed of the same material, and the storage node contact plugs are integrally formed with the first electrodes.

5. The semiconductor device of claim 1, wherein the second electrode has a cylindrical structure.

6. The semiconductor device of claim 5, wherein the second electrode has an L-shaped structure in which a lower portion thereof extends in a direction away from the center of the cylindrical structure.

7. The semiconductor device of claim 1, wherein the storage node contact plugs are arranged along a zigzag line.

8. The semiconductor device of claim 2, wherein the plate electrode is further disposed over the dielectric layer to fill a gap between each of the second electrodes and the second interlayer dielectric layer.

9. A method for fabricating a semiconductor device, the method comprising:
forming a plurality of storage node contact plugs passing through a first interlayer dielectric layer and forming a first electrode having a pillar shape;
forming a first spacer surrounding the sidewall of each of the first electrodes;
forming a second electrode and a second spacer over each of the first spacers to surround the first electrodes;
forming a second interlayer dielectric layer filling a gap between neighboring second electrodes; and
performing a planarization process to separate the first electrodes and the second electrodes and expose the top surfaces of the first and second spacers.

10. The method of claim 9, wherein the second interlayer dielectric layer and the second spacers are formed of the same material, and the first spacers are formed of a material having an etch selectivity with respect to the second interlayer dielectric layer and the second spacers.

11. The method of claim 10, further comprising:
selectively removing the first spacers to form storage node holes opening a gap between each of the first electrodes and the second electrodes;
forming a dielectric layer over a resulting structure including the storage node holes; and
forming a plate electrode over the dielectric layer to fill the storage node holes.

12. The method of claim 9, wherein the first spacers and the second spacers are formed of the same material, and the second interlayer dielectric layer is formed of a material having an etch selectivity with respect to the first spacers and the second spacers.

13. The method of claim 12, further comprising:
selectively forming the first and second spacers to form first storage node holes opening a gap between each of the first electrodes and the second electrodes and simultaneously forming second storage node holes opening a gap between each of the second electrodes and the second interlayer dielectric layer;
forming a dielectric layer over a resulting structure including the first and second storage node holes; and
forming a plate electrode over the dielectric layer to fill the first and second storage node holes.

14. The method of claim 9, wherein the forming of the storage node contact plugs and the first electrodes comprises:
etching the first interlayer dielectric layer to form a plurality of storage node contact holes;
forming a conductive layer to fill the storage node contact holes and cover the first interlayer dielectric layer; and
simultaneously forming the storage node contact plugs and the first electrode by selectively etching the conductive layer until the first interlayer dielectric layer is exposed.

15. The method of claim 9, wherein each of the first electrodes is formed to be in contact with the center of a corresponding one of the storage node contact plugs.

16. The method of claim 9, wherein each of the first spacers is formed so that the edge of a corresponding one of the storage node contact plugs is exposed.

17. The method of claim 9, wherein the forming of the second electrodes and the second spacers comprises:
sequentially forming a conductive layer and an insulation layer for a spacer along the surface of the structure including the first spacers; and
forming the second spacers and the second electrodes by performing an entire-surface etch process until the first interlayer dielectric layer is exposed.

18. The method of claim 17, wherein each of the second electrodes has an L-shaped structure in which a lower portion thereof extends in a direction away from the corresponding first electrode.

19. The method of claim 9, wherein the planarization process is performed using chemical mechanical polishing.

20. The method of claim 9, wherein the second electrode has a cylindrical structure at the time when the planarization process is completed.
